(19) United States
(12) Patent Application Publication
(10) Pub. No.: US 2025/0174605 A1
(43) Pub. Date: May 29, 2025

(54) DISPLAY DEVICE WITH REDUCED LIGHT REFLECTION

(71) Applicant: SAMSUNG DISPLAY CO., LTD., YONGIN-SI (KR)

(72) Inventors: YISEOP SHIM, Yongin-si (KR); KYEONGJONG KIM, Yongin-si (KR); SU JEONG KIM, Yongin-si (KR); YUN-HEE PARK, Yongin-si (KR); HYUNSEUNG LEE, Yongin-si (KR); KYUWON CHO, Yongin-si (KR); KYUNGSEON TAK, Yongin-si (KR)

(21) Appl. No.: 18/811,276

(22) Filed: Aug. 21, 2024

(30) Foreign Application Priority Data
Nov. 23, 2023 (KR) 10-2023-0164180

(51) Int. Cl. H01L 25/075; H01L 33/44; H01L 33/50

(52) U.S. Cl. CPC H01L 25/0753; H10H 20/84; H10H 20/8512; H10H 20/8514; H10H 20/8516

(57) ABSTRACT

Provided is a display device including a display panel divided into a plurality of light emitting regions in which a plurality of light emitting elements are disposed and a non-light emitting region adjacent to the light emitting regions, and a color filter layer disposed on the display panel. The color filter layer includes a plurality of filter parts which overlap the light emitting regions, respectively, and in which a single type of color filters is disposed, respectively, and a blocking part which overlaps the non-light emitting region and in which at least two color filters overlap. The blocking part has a thickness of about 3.0 μm to about 10.0 μm, and an optical density of about 3.0 or more.

### CROSS-REFERENCE TO RELATED APPLICATION

This U.S. non-provisional patent application claims priority under 35 U.S.C. § 119 of Korean Patent Application No. 10-2023-0164180, filed on Nov. 23, 2023, in the Korean Intellectual Property Office, the content of which is incorporated by reference herein in its entirety.

### 1. TECHNICAL FIELD

The present disclosure relates to a display device and, more specifically, to a display device with reduced light reflection.

### 2. DISCUSSION OF THE RELATED ART

Various display devices such as those used in multimedia devices such as televisions, mobile phones, tablet computers, and portable game consoles are being developed. The display devices may include various optical functional layers for providing excellent quality color images to a user.

Meanwhile, in order to implement various types of display devices such as a display device including a curved surface, a rollable display device, or a foldable display device, research on a thin display device has recently been conducted. It is possible to reduce the number of optical functional layers and implement a thin display device by including an optical functional layer which includes various functions.

### SUMMARY

The present disclosure provides a display device having improved light characteristics by reducing external light reflection and improving display efficiency.

An embodiment of the inventive concept provides a display device including a display panel divided into a plurality of light emitting regions in which a plurality of light emitting elements are disposed and a non-light emitting region adjacent to the light emitting regions, and a color filter layer disposed on the display panel. The color filter layer includes a plurality of filter parts which overlap the light emitting regions, respectively, and in which a single type of color filter is disposed, respectively, and a blocking part which overlaps the non-light emitting region and in which at least two color filters overlap. The blocking part has a thickness of about 3.0 μm to about 10.0 μm, and an optical density of about 3.0 or more.

In an embodiment, the color filter layer may include a first color filter that transmits first color light, a second color filter that transmits second color light, and a third color filter that transmits third color light.

In an embodiment, the blocking part may be formed by stacking a portion of the first color filter and a portion of the third color filter.

In an embodiment, the blocking part may have an optical density of about 3.0 to about 5.0.

In an embodiment, the first color filter disposed in the blocking part may have a thickness of about 2.0 μm to about 4.5 μm, and the third color filter disposed in the blocking part may have a thickness of about 1.0 μm to about 3.0 μm.

In an embodiment, the blocking part may be formed by stacking a portion of each of the first to third color filters.

In an embodiment, the blocking part may have an optical density of about 4.0 to about 5.0.

In an embodiment, the first color filter disposed in the blocking part may have a thickness of about 1.0 μm to about 3.0 μm, the second color filter disposed in the blocking part may have a thickness of about 2.0 μm to about 4.0 μm, and the third color filter disposed in the blocking part may have a thickness of about 1.0 μm to about 3.0 μm.

In an embodiment, the first color filter may include a first pigment, the second color filter may include a second pigment, and the third color filter may include a third pigment.

In an embodiment, each of the first to third color filters may further include a scatterer.

In an embodiment, the color filter layer may further include an overcoat layer which covers the first to third color filters.

In an embodiment, one color filter among the first to third color filters may be disposed in each of the filter parts.

In an embodiment, a reflectance to external light of the blocking part may be about 0.1 or less.

In an embodiment, each of the light emitting elements may emit the first color light, and on a plane, the display device may be divided into a first pixel region that emits the second color light different from the first color light, a second pixel region that emits the third color light different from the first and second color lights, and a third pixel region that emits the first color light.

In an embodiment, the display device may further include a light control layer disposed between the display panel and the color filter layer, wherein the light control layer may include a first light control part that overlaps the first pixel region and converts the first color light into the second color light, a second light control part that overlaps the second pixel region and converts the first color light into the third color light, and a third light control part that overlaps the third pixel region and transmits the first color light.

In an embodiment, the display device may further include a low refractive layer disposed between the light control layer and the color filter layer, and an anti-reflection layer disposed on the color filter layer.

In an embodiment of the inventive concept, a display device includes a display panel divided into a plurality of light emitting regions in which a plurality of light emitting elements are disposed and a non-light emitting region adjacent to the light emitting regions, a light control layer disposed on the display panel, and a color filter layer disposed on the light control layer. The color filter layer includes a plurality of filter parts which overlap the light emitting regions, respectively, and in which a single type of color filter is disposed, respectively, and a blocking part which overlaps the non-light emitting region and in which at least two color filters overlap. The blocking part has an optical density of about 3.0 to about 5.0.

In an embodiment, the color filter layer may include a first color filter that transmits first color light, a second color filter that transmits second color light, and a third color filter that transmits third color light.

In an embodiment, the blocking part may have be formed by stacking a portion of the first color filter and a portion of the third color filter, and the blocking part may have a thickness of about 3.0 μm to about 7.5 μm.

In an embodiment, a reflectance to external light of the blocking part may be about 0.1 or less.

### BRIEF DESCRIPTION OF THE FIGURES

The accompanying drawings are included to provide a further understanding of the inventive concept, and are incorporated in and constitute a part of this specification. The drawings illustrate exemplary embodiments of the inventive concept and, together with the description, serve to explain principles of the inventive concept. In the drawings:

FIG. 1 is a perspective view illustrating a display device according to an embodiment of the present inventive concept;

FIG. 2 is a cross-sectional view of the display device according to the embodiment of the present inventive concept;

FIG. 3 is a plan view of a display panel according to an embodiment of the inventive concept;

FIG. 4 is an enlarged plan view illustrating a portion of a display region in the display device according to the embodiment of the present inventive concept;

FIG. 5A is a cross-sectional view, of the display device, taken along line II-II′ of FIG. 4;

FIG. 5B is an enlarged view of region AA′ of FIG. 5A;

FIG. 6A is a cross-sectional view, of a display device according to an embodiment of the present inventive concept, taken along line II-II′ of FIG. 4;

FIG. 6B is an enlarged view of region BB′ of FIG. 6A;

FIG. 7 is a cross-sectional view of a display device according to an embodiment of the present inventive concept;

FIG. 8 is a cross-sectional view of a display device according to an embodiment of the inventive concept;

FIGS. 9A, 9B and 9C are diagrams showing optical densities and reflectances depending on thicknesses of a first color filter illustrated in FIG. 5A;

FIGS. 10A, 10B and 10C are diagrams showing optical densities and reflectances depending on thicknesses of a second color filter illustrated in FIG. 5A;

FIGS. 11A, 11B and 11C are diagrams showing optical densities and reflectances depending on thicknesses of a third color filter illustrated in FIG. 5A; and

FIGS. 12A, 12B and 12C are diagrams showing optical densities and reflectances depending on thicknesses of blocking parts illustrated in FIGS. 5A and 6A.

### DETAILED DESCRIPTION

The inventive concept may be modified in many alternate forms, and thus specific embodiments will be exemplified in the drawings and described in detail in the detailed description. It should be understood, however, that it is not intended to necessarily limit the inventive concept to the particular forms disclosed, but rather, is intended to cover all modifications, equivalents, and alternatives falling within the spirit and scope of the inventive concept.

In the present specification, when a component (or a region, a layer, a portion, etc.) is referred to as being “on,” “connected to,” or “coupled to” another component, it means that the component may be directly disposed on/connected to/coupled to the other component, or that a third component may be disposed therebetween.

Like reference numerals may refer to like components throughout the specification and the figures. While each drawing may represent one or more particular embodiments of the present disclosure, drawn to scale, such that the relative lengths, thicknesses, and angles can be inferred therefrom, it is to be understood that the present invention is not necessarily limited to the relative lengths, thicknesses, and angles shown. Changes to these values may be made within the spirit and scope of the present disclosure, for example, to allow for manufacturing limitations and the like.

It will be understood that, although the terms “first”, “second”, etc. may be used herein to describe various elements, these elements should not necessarily be limited by these terms. These terms are used to distinguish one element from another. For example, a first component could be termed a second component, and, similarly, a second component could be termed a first component, without departing from the scope of the inventive concept. The terms of a singular form may include plural forms unless the context clearly indicates otherwise.

In addition, terms such as “below,” “on the lower portion of,” “above,” and “on the upper portion of” are used to describe the relationship of the configurations shown in the drawings. The terms are used as a relative concept and are described with reference to the direction indicated in the drawings.

Hereinafter, embodiments of the inventive concept will be described with reference to the accompanying drawings.

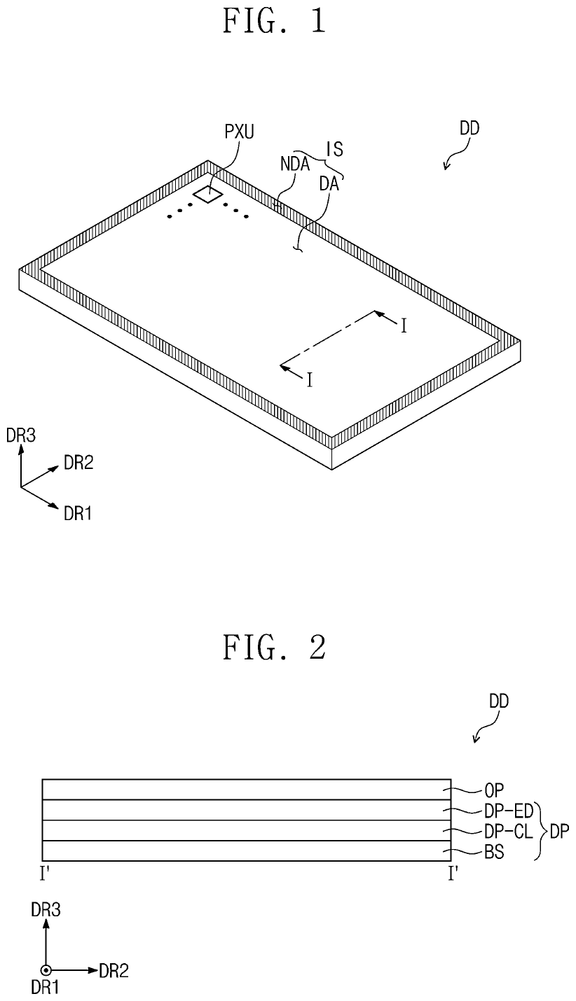

FIG. 1 is a perspective view illustrating a display device according to an embodiment of the present inventive concept. FIG. 2 is a cross-sectional view of the display device according to the embodiment of the present inventive concept. FIG. 2 is a cross-sectional view taken long line I-I′ of FIG. 1.

The display device DD of an embodiment may be a device that is activated according to an electrical signal. For example, the display device DD may be a large-sized device such as a television, a computer monitor, or an outdoor digital billboard. In addition, the display device DD may be a small or medium-sized device such as a personal computer, a laptop computer, a personal digital terminal, a car navigation system, a game console, a smart phone, a tablet computer, or a camera. However, these are merely presented as an example, and thus the display device DD may be adopted in other electronic devices without departing from the inventive concept.

The display device DD may be rigid or flexible. The term “flexible” means having bendable characteristics. For example, the flexible display device DD may include a curved device, a rollable device, or a foldable device.

First to third directions DR1, DR2 and DR3 described in this specification are relative concepts and may be converted into other directions. In addition, the directions indicated by the first to third directions DR1, DR2 and DR3 may be described as first to third directions DR1, DR2, and DR3, and the same reference symbols may be used. In this specification, the first direction DR1 and the second direction DR2 are orthogonal to each other, and the third direction DR3 may be a normal line direction with respect to the plane defined by the first direction DR1 and the second direction DR2.

The display device DD may have a thickness direction along the third direction DR3. In this specification, a front surface (or top surface) and a rear surface (or bottom surface) of members of the display device DD may be defined with respect to the third direction DR3. For example, the front surface (or top surface) and the rear surface (or bottom surface) of each of members constituting the display device DD may be disposed opposite to each other along the third direction DR3, and the normal direction to each of the front surface and the rear surface may be parallel to the third direction DR3. The separation distance between the front surface and the rear surface defined along the third direction DR3 may be the thickness of the member.

In the present specification, “on a plane” or “in a plan view” may be defined as a state when viewed along the third direction DR3. In the present specification, “on a cross-section” may be defined as a state when viewed along the first direction DR1 or the second direction DR2. Meanwhile, the directions indicated by the first to third directions DR1, DR2 and DR3 may be a relative concept and thus may be converted to other directions.

The display device DD may display an image (or a video) through a display surface IS. The display surface IS may include the plane defined by the first direction DR1 and the second direction DR2. The display surface IS may include a display region DA and a non-display region NDA. In the display region DA, a plurality of pixels PXU may be disposed, and in the non-display region NDA, the pixels PXU might not disposed. The non-display region NDA may be defined by the edges of the display surface IS. For example, the non-display region NDA may surround the display region DA. However, the embodiment of the present inventive concept is not necessarily limited thereto, and in an embodiment of the present inventive concept, the non-display region NDA may be omitted or disposed only one side of the display region DA.

The pixels PXU may define a pixel row and a pixel column. The pixels PXU may include a plurality of pixels which provide light beams having different colors.

In an embodiment of the present inventive concept, the display device DD having a flat display surface IS is illustrated, but the embodiment of the present inventive concept is not necessarily limited thereto. For example, the display device DD may include a curved display surface or a three-dimensional display surface. The three-dimensional display surface may include a plurality of display areas indicating different directions.

Referring to FIG. 2, the display device DD of the present inventive concept may include a display panel DP and a light control panel OP disposed on the display panel DP. The display panel DP may include a base substrate BS, a circuit layer DP-CL, and a display layer DP-ED which are sequentially stacked along the third direction DR3. For example, the circuit layer DP-CL may be interposed between the base substrate BS and the display layer DP-ED. The light control panel OP may be disposed on the display layer DP-ED. For example, the light control panel OP may be directly disposed on the display layer DP-ED so that a bottom surface of the light control panel OP is in contact with a top surface of the display layer DP-ED.

In the specification, that one component is “directly disposed/directly formed” on another component means that a third component is not disposed between one component and another component. That is, that one component is “directly disposed/directly formed” on another component means that one component is in “contact” with another component.

In an embodiment, a charge layer may be disposed between the display panel DP and the light control panel OP. For example, the display panel DP and the light control panel OP may be spaced apart from each other with the charge layer interposed therebetween. In this case, the light control panel OP may be manufactured in a separate process, and then may be provided on the display panel DP.

In an embodiment of the present inventive concept, the display panel DP may be referred to as a lower panel or a lower display substrate, and the light control panel OP may be referred to as an upper panel or an upper display substrate.

In the display device DD of an embodiment, the base substrate BS may be a support substrate on which the circuit layer DP-CL and the display layer DP-ED are provided. The circuit layer DP-CL may include an insulation layer and/or a circuit element. For example, the circuit element may include a signal line, a pixel driving circuit, etc. The circuit layer DP-CL may be formed through a forming process of an insulation layer, a semiconductor layer, and a conductive layer by coating, deposition, etc. and a patterning process of the insulation layer, the semiconductor layer, and the conductive layer by a photolithography process.

The display layer DP-3D may include a display element. The display device DD may include a light emitting element that generates light and provides the light to the light control panel OP. The display panel DP including the display layer DP-ED may provide source light to the light control panel OP disposed thereon.

The light control panel OP may convert a wavelength of light provided from the display panel DP or transmit a part of the provided light. The light control panel OP may include a light control part which converts a wavelength or transmits the light, and structures for increasing conversion efficiency of emitted light.

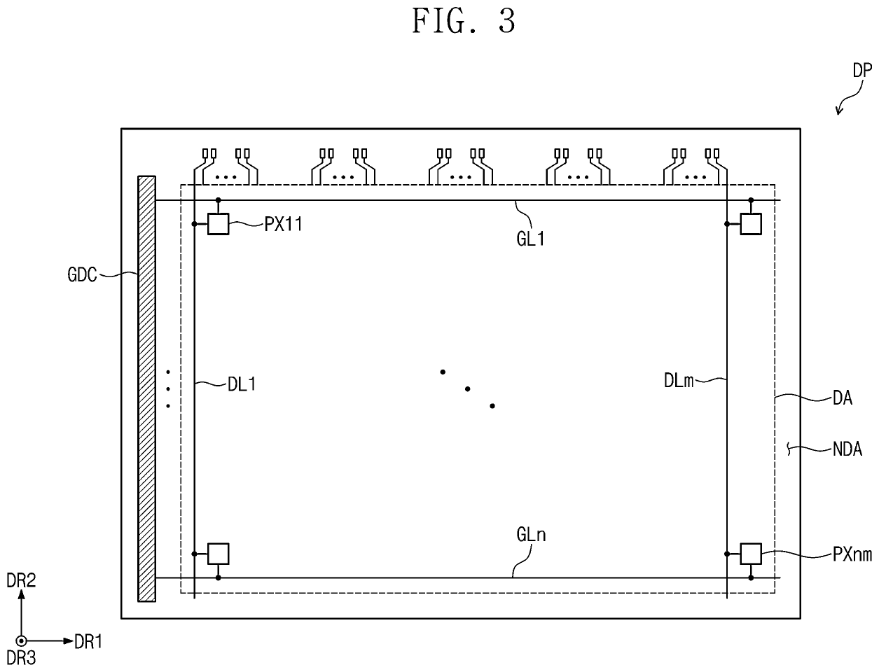

FIG. 3 is a plan view of a display panel according to an embodiment of the present inventive concept. FIG. 3 illustrates a planar arrangement of signal lines GL1 to GLn and DL1 to DLm and pixels PX11 to PXnm. The signal lines GL1 to GLn and DL1 to DLm may include a plurality of gate lines GL1 to GLn and a plurality of data lines DL1 to DLm.

Each of the pixels PX11 to PXnm is connected to a corresponding gate line among the plurality of gate lines GL1 to GLn and a corresponding data line among the plurality of data lines DL1 to DLm. Each of the pixels PX11 to PXnm may include a pixel driving circuit and a display element. According to the configuration of the pixel driving circuit of the pixels PX11 to PXnm, more types of signal lines may be provided in the display panel DP.

FIG. 3 exemplarily illustrates the pixels PX11 to PXnm disposed in the form of a matrix, but the embodiment of the present inventive concept is not necessarily limited thereto. For example, the pixels PX11 to PXnm may be disposed in a PENTILE™ arrangement where PENTILE™ is an arrangement of luminous areas manufactured by SAMSUNG. For example, the points, at which the pixels PX11 to PXnm are disposed, may correspond to apexes of a diamond. The gate driving circuit GDC may be integrated in the display panel DP through an oxide silicon gate driver circuit (OSG) or an amorphous silicon gate driver circuit (ASG) process.

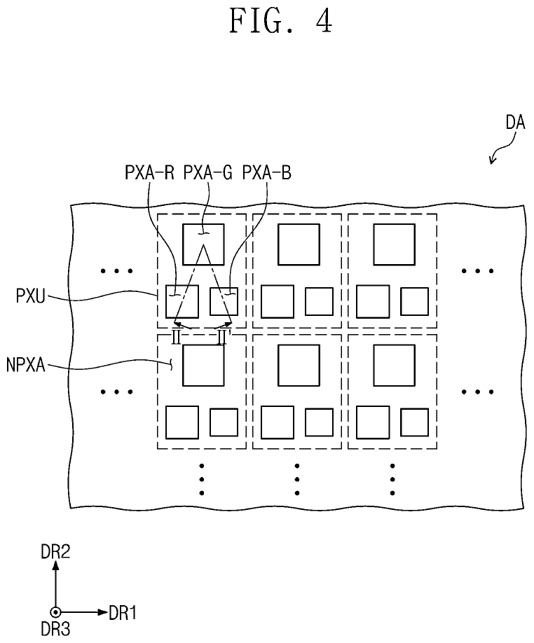

FIG. 4 is an enlarged plan view illustrating a portion of a display region in the display device according to the embodiment of the present inventive concept.

Referring to FIG. 4, pixels PXU may each be arranged along the first direction DR1 and the second direction DR2. The pixels PXU may include a first pixel, a second pixel, and a third pixel that emit light beams in different wavelength regions. The first pixel, the second pixel, and the third pixel may emit red light, green light, and blue light, respectively. FIG. 4 illustrates a first pixel region PXA-R, a second pixel region PXA-G, and a third pixel region PXA-B respectively representing the first pixel, the second pixel, and the third pixel. The first pixel region PXA-R may be a region in which the light generated in the first pixel is provided to the outside, the second pixel region PXA-G may be a region in which the light generated in the second pixel is provided to the outside, and the third pixel region PXA-B may be a region in which the light generated in the third pixel is provided to the outside. The first to third pixel regions PXA-R, PXA-G, and PXA-B may be separated without overlapping each other in a plan view.

In an embodiment of the present inventive concept, the first pixel region PXA-R may be a red light emitting region that emits red light, the second pixel region PXA-G may be a green light emitting region that emits green light, and the third pixel region PXA-B may be a blue light emitting region that emits blue light. However, the embodiment of the present inventive concept is not necessarily limited thereto, and the display region DA may further include a pixel region emitting white light in addition to the first to third pixel regions PXA-R, PXA-G, and PXA-B.

A peripheral region NPXA may at least partially surround each of the first pixel region PXA-R, the second pixel region PXA-G, and the third pixel region PXA-B. As used herein, the phrase “at least partially surround” is understood to mean that the surrounding element contacts the surrounded element on at least one side or portion thereof, may contact the surrounded element on two sides, whether those sides are opposite sides or proximate sides, may contact the surrounded element on more than two sides, and may even completely surround the surrounded element. The peripheral region NPXA may be disposed among the first pixel region PXA-R, the second pixel region PXA-G, and the third pixel region PXA-B. The peripheral region NPXA may set boundaries of the first to third pixel regions PXA-R, PXA-G, and PXA-B and may prevent color mixing among the first to third pixel regions PXA-R, PXA-G, and PXA-B. A structure preventing color mixing between the first to third pixel regions PXA-R, PXA-G, and PXA-B may be disposed in the peripheral regions NPXA.

Although FIG. 4 exemplarily illustrates the display device DD (see FIG. 1) including the first to third pixel regions PXA-R, PXA-G, and PXA-B having the same planar shape and different planar areas, the embodiment of the present inventive concept is not necessarily limited thereto. For example, the areas of the first to third pixel regions PXA-R, PXA-G, and PXA-B may be all the same, or the area of at least one type of pixel region may be different from the area of the other types of pixel regions. The areas of the first to third pixel regions PXA-R, PXA-G, and PXA-B may be set according to a light emission color.

Referring to FIG. 4, the first to third pixel regions PXA-R, PXA-G, and PXA-B may have a rectangular shape in a plan view. However, the embodiment of the present inventive concept is not necessarily limited thereto, and the first to third pixel regions PXA-R, PXA-G, and PXA-B may have various polygonal shapes (substantially polygonal shapes) such as a diamond or a pentagon in a plan view. For example, the first to third pixel regions PXA-R, PXA-G, and PXA-B may have a rectangular shape (a substantially rectangular shape) of which the corner regions are rounded in a plan view.

Although FIG. 4 exemplarily illustrates that the second pixel region PXA-G is disposed in the first row while the first pixel region PXA-R and the third pixel region PXA-B are disposed in the second row, the arrangement of the first to third pixel regions PXA-R, PXA-G, and PXA-B is not necessarily limited thereto and may be variously changed. For example, the first to third pixel regions PXA-R, PXA-G, and PXA-B may be disposed in the same row.

The plurality of pixel regions PXA-R, PXA-G, and PXA-B may be arranged in a stripe shape, or may be arranged in PENTILE™ or Diamond Pixel™ However, the embodiment of the inventive concept is not necessarily limited thereto, and the arrangement order and arrangement form of the plurality of pixel regions PXA-R, PXA-G, and PXA-B may be provided in various combinations according to characteristics of display quality required in the display device DD (see FIG. 1).

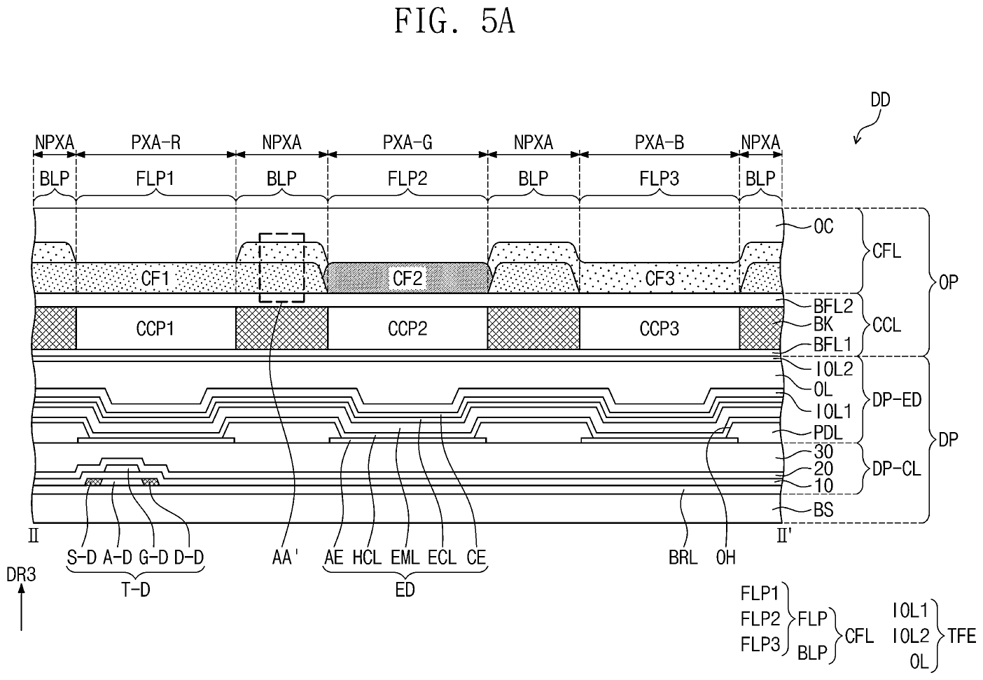

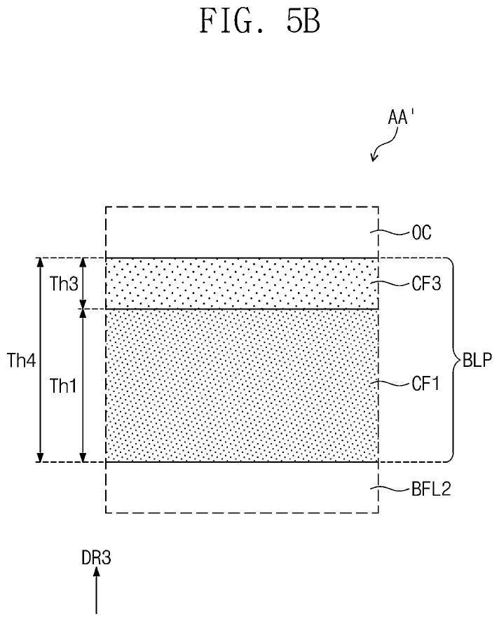

FIG. 5A is a cross-sectional view of the display device, taken along line II-II′ of FIG. 4. FIG. 5B is an enlarged view of region AA′ of FIG. 5A.

Referring to FIG. 5A, the display device DD may include a display panel DP and a light control panel OP disposed on the display panel DP. To the extent that an element has not been described in detail, it may be assumed that the element is at least similar to corresponding elements that have been described in previous figures.

The display panel DP may include a base substrate BS, a circuit layer DP-CL disposed on the base substrate BS, and a display layer DP-ED disposed on the upper portion of the circuit layer DP-CL. For example, the circuit layer DP-CL may be interposed between the base substrate BS and the display layer DP-ED. The light control panel OP may include a light control layer CCL disposed on the upper portion of the display layer DP-ED and a color filter layer CFL disposed on the upper portion of the light control layer CCL.

The base substrate BS may be a member providing a base surface on which the circuit layer DP-CL is disposed. The base substrate BS may include a single layer or multiple layers. For example, the base substrate BS may include three-layered structure constituted by a polymer resin layer, an adhesive layer, and a polymer resin layer. For example, the polymer resin layer may include a polyimide-based resin. In addition, the polymer resin layer may include at least one of an acrylate-based resin, a methacrylate-based resin, a polyisoprene-based resin, a vinyl-based resin, an epoxy-based resin, a urethane-based resin, a cellulose-based resin, a siloxane-based resin, a polyamide-based resin, or a perylene-based resin.

In the specification, the polyimide-based resin means including a functional group of polyimide. The same description may be applied to the acrylate-based resin, the methacrylate-based resin, the polyisoprene-based resin, the vinyl-based resin, the epoxy-based resin, the urethane-based resin, the cellulose-based resin, the siloxane-based resin, the polyamide-based resin, the polyamide-based resin, and the perylene-based resin.

The circuit layer DP-CL may include a lower buffer layer BRL disposed on the upper portion of the base substrate BS, a first insulation layer 10 disposed on the lower buffer layer BRL, a second insulation layer 20 disposed on the upper portion of the first insulation layer 10, and a third insulation layer 30 disposed on the upper portion of the second insulation layer 20. For example, the second buffer insulation layer 20 may be interposed between the first and the third insulation layers 10 and 30. For example, the lower buffer layer BRL, the first insulation layer 10, and the second insulation layer 20 may be inorganic layers, and the third insulation layer 30 may be an organic layer.

In addition, the circuit layer DP-CL may include transistors T-D. The transistors T-D may include an active A-D, a source S-D, a drain D-D, and a gate G-D. The active A-D, the source S-D, the drain D-D, and the gate G-D may be regions that are divided according to a doping concentration or conductivity of a semiconductor pattern. The active A-D, the source S-D, and the drain D-D may be disposed on the upper portion of the lower buffer layer BRL, and the gate G-D may be disposed on the upper portion of the first insulation layer 10. The transistors T-D may be a switching transistor or a driving transistor for driving a light emitting element ED of the display layer DP-ED. However, this is exemplary, and the transistors T-D are not necessarily limited thereto.

The display layer DP-ED may include a pixel defining film PDL in which a pixel opening OH is defined, and the light emitting element ED. The light emitting element ED may include a first electrode AE exposed in the pixel opening OH, a second electrode CE facing the first electrode AE, and an emission layer EML disposed between the first electrode AE and the second electrode CE. The light emitting element ED may further include a hole transport region HCL disposed between the first electrode AE and the emission layer EML, and an electron transport region ECL disposed between the emission layer EML and the second electrode CE. The hole transport region HCL may include at least one of a hole injection layer, a hole transport layer, or an electron blocking layer. The electron transport region ECL may include at least one of an electron injection layer, an electron transport layer, or a hole blocking layer.

The first electrode AE may be an anode or a cathode. The first electrode AE may be a pixel electrode. The first electrode AE may be a transmissive electrode, a transflective electrode, or a reflective electrode. The second electrode CE may be a common electrode. The second electrode CE may be a cathode or an anode, but the embodiment of the present inventive concept is not necessarily limited thereto. For example, when the first electrode AE is an anode, the second electrode CE may be a cathode, and when the first electrode AE is a cathode, the second electrode CE may be an anode. The second electrode CE may be a transmissive electrode, a transflective electrode, or a reflective electrode.

The emission layer EML may emit first color light. For example, the emission layer EML may generate blue light. The emission layer EML may generate light in a wavelength region of about 410 nm to about 480 nm. FIG. 5A illustrates the light emitting element ED including one emission layer EML, but the light emitting element ED may include a plurality of emission layers. For example, the light emitting element ED may be a light emitting element in a tandem structure.

The emission layer EML may include a fluorescent or phosphorescent material. For example, the emission layer EML may include anthracene derivatives, pyrene derivatives, fluoranthene derivatives, chrysene derivatives, dihydrobenzanthracene derivatives, or triphenylene derivatives. In addition, the emission layer EML may include an organometallic complex as a luminescent material.

FIG. 5A illustrates that the emission layer EML is provided as a common layer and overlaps the pixel regions PXA-R, PXA-G, and PXA-B and the peripheral regions NPXA. In the current embodiment, the pixel regions PXA-R, PXA-G, and PXA-B and the peripheral regions NPXA may be referred to as light emitting regions PXA-R, PXA-G, and PXA-B and a non-light emitting region NPXA defined in the display device DD, respectively. In some embodiments, the emission layer EML may be patterned in the pixel opening OH and overlap each of the light emitting regions PXA-R, PXA-G, and PXA-B and might not to overlap the non-light emitting region NPXA.

A pixel opening OH of the pixel defining film PDL may expose at least a portion of the first electrode AE. The pixel defining film PDL may overlap the non-light emitting region NPXA and might not overlap the light emitting regions PXA-R, PXA-G, and PXA-B. The pixel defining film PDL may include an organic material. For example, the pixel defining film PDL may be optically transparent. The pixel defining film PDL may have a transmittance of about 85% or more for light in a wavelength region of about 380 nm to about 780 nm.

In the present specification, the term “overlapping” of the two components is not necessarily limited to cases having the same area and the same shape in a plan view, but also includes the case where the two components have different areas and/or different shapes.

The display layer DP-ED may include a thin-film encapsulation layer TFE which protects the second electrode CE. The thin-film encapsulation layer TFE may include an organic material or inorganic material. The thin-film encapsulation layer TFE may have a multi-layered structure in which an inorganic layer and an organic layer are alternately placed. In an embodiment of the present inventive concept, the thin-film encapsulation layer TFE may include a first inorganic encapsulation layer IOL1, an organic encapsulation layer OL, and a second inorganic encapsulation layer IOL2. The first and second inorganic encapsulation layer IOL1 and IOL2 may protect the light emitting element ED from external moisture, and the organic encapsulation layer OL may prevent pit defect of the light emitting element ED caused by foreign substances introduced during a manufacture process. The display panel DP may further include a refractive index control layer above the thin-film encapsulation layer TFE and increase light output efficiency.

The light control layer CCL may be disposed on the display layer DP-ED. The light control layer CCL may include a light conversion body. For example, the light conversion body may be a quantum dot, a phosphor, or the like. The light conversion body may release the light by converting the wavelength thereof. For example, the light control layer CCL may a layer containing the quantum dot or a layer containing the phosphor.

The light control layer CCL may include a plurality of light control parts CCP1, CCP2 and CCP3. The light control parts CCP1, CCP2, and CCP3 may be spaced apart from each other. The light control layer CCL may include a first light control part CCP1 which converts the first color light provided in the light emitting element ED to second color light, a second light control part CCP2 that converts the first color light to third color light, and a third light control part CCP3 that transmits the first color light.

The light control layer CCL may include a bank BK disposed between neighboring pairs of the light control parts CCP1, CCP2, and CCP3. The bank BK may be spaced apart from each other. FIG. 3 illustrates that the bank BK do not overlap the light control parts CCP1, CCP2 and CCP3, but in some embodiments, a portion of the edges of the light control parts CCP1, CCP2 and CCP3 may overlap the bank BK.

The bank BK may include a base resin and an additive. The base resin may be formed of various resin compositions, which may be generally referred to as a binder. The additive may include a coupling agent and/or photoinitiator. The additive may further include a dispersant.

The bank BK may include a black coloring agent for shielding light. For example, the bank BK may include a black pigment and black dye mixed in the base resin. For example, the black component may include carbon black or a metal such as chromium, or an oxide thereof.

The light control layer CCL may further include a first barrier layer BFL1 and a second barrier layer BFL2. The first barrier layer BFL1 may prevent the penetration of moisture and/or oxygen (hereinafter, referred to as “moisture/oxygen”). The first barrier layer BFL1 may be disposed on the light control parts CCP1, CCP2, and CCP3 and block the light control parts CCP1, CCP2 and CCP3 from being exposed to moisture/oxygen. The second barrier layer BFL2 may be provided on the light control parts CCP1, CCP2, and CCP3. The first barrier layer BFL1 and the second barrier layer BFL2 may each at least partially cover the top surface and the bottom surface, respectively, of the light control parts CCP1, CCP2, and CCP3. FIG. 5A exemplarily illustrates a structure in which the light control layer CCL includes the first and second barrier layers BFL1 and BFL2, but the embodiment of the present inventive concept is not necessarily limited thereto. For example, the second barrier layer BFL2 may be omitted.

Each of the first and second barrier layers BFL1 and BFL2 may include at least one inorganic layer. For example, each of the first barrier layer BFL1 and the second barrier layer BFL2 may include an inorganic material. For example, each of the first barrier layer BFL1 and the second barrier layer BFL2 may include a silicon nitride, an aluminum nitride, a zirconium nitride, a titanium nitride, a hafnium nitride, a tantalum nitride, a silicon oxide, an aluminum oxide, a titanium oxide, a tin oxide, a cerium oxide, a silicon oxynitride, a metal thin film which secures a light transmittance, etc. Meanwhile, each of the first barrier layer BFL1 and the second barrier layer BFL2 may further include an organic film. Each of the first barrier layer BFL1 and the second barrier layer BFL2 may be composed of a single layer or a plurality of layers.

The color filter layer CFL may be disposed on the light control layer CCL. The color filter layer CFL may include color filters CF1, CF2, and CF3 and an overcoat layer OC that at least partially covers the color filters CF1, CF2, and CF3.

The color filter layer CFL may include a first color filter CF1 that transmits the second color light, a second color filter CF2 that transmits the third color light, and a third color filter CF3 that transmits the first color light. For example, the first color filter CF1 may be a red filter, the second color filter CF2 may be a green filter, and the third color filter CF3 may be a blue filter. Each of the first to third color filters CF1, CF2, and CF3 may include a polymeric photosensitive resin and a pigment or dye. The first color filter CF1 may include a red pigment or dye, the second color filter CF2 may include a green pigment or dye, and the third color filter CF3 may include a blue pigment or dye. However, the embodiment of the present inventive concept is not necessarily limited thereto, and the third color filter CF3 might not include a pigment or dye. The third color filter CF3 may include a polymeric photosensitive resin and might not include a pigment or dye. The third color filter CF3 may be transparent. The third color filter CF3 may be formed of a transparent photosensitive resin. For example, one portion of the third color filter CF3 may include a blue pigment or dye, and another portion may be formed of a transparent photosensitive resin.

The first to third color filters CF1, CF2, and CF3 may be disposed in the same layer, corresponding to the first light emitting region PXA-R, the second light emitting region PXA-G, and the third light emitting region PXA-B, respectively. For example, the first to third color filters CF1, CF2, and CF3 may be disposed on the light control layer CCL, corresponding to the first light emitting region PXA-R, the second light emitting region PXA-G, and the third light emitting region PXA-B, respectively. The first to third color filters CF1, CF2, and CF3 may have substantially the same height when measured from a top surface of the light control layer CCL in the first light emitting region PXA-R, the second light emitting region PXA-G, and the third light emitting region PXA-B, respectively. In addition, the height measured from a top surface where the third color filter CF3 overlaps the non-light emitting region NPXA may be different from the height measured from a top surface where the third color filter CF3 overlaps the third light emitting region PXA-B. For example, the top surface of a portion of the third color filter CF3 overlapping the non-light emitting region NPXA may be disposed at higher level than the top surface of a portion of the third color filter CF3 overlapping the third light emitting region PXA-B. However, the embodiment of the inventive concept is not necessarily limited thereto, and unlike the configuration illustrated in FIG. 5A, each of the first and second color filters CF1 and CF2 may have substantially the same height in the first light emitting region PXA-R and the second light emitting region PXA-G, and the height of the third color filter CF3 may be different from those of the first and second color filters CF1 and CF2 in the third light emitting region PXA-B. For example, the height of the third color filter CF3 overlapping the third light emitting region PXA-B may be relatively higher than those of the first and second color filters CF1 and CF2 overlapping the first light emitting region PXA-R and the second light emitting region PXA-G, respectively.

According to an embodiment of the present inventive concept, the color filter layer CFL may include a filter part FLP which overlaps the light emitting regions PXA-R, PXA-G, and PXA-B and in which one among the color filters CF1, CF2, and CF3 is disposed, and a blocking part BLP which overlaps the non-light emitting region NPXA and in which at least two among the color filters CF1, CF2, and CF3 are disposed. For example, the filter part FLP may include a first filter part FLP1 corresponding to the first color filter CF1 disposed in the first light emitting region PXA-R, a second filter part FLP2 corresponding to the second color filter CF2 disposed in the second light emitting region PXA-G, and a third filter part FLP3 corresponding to the third color filter CF3 disposed in the third light emitting region PXA-B.

The blocking part BLP may be defined (or configured) by at least two color filters CF1, CF2, and CF3 disposed in the non-light emitting region NPXA. For example, the blocking part BLP may correspond to the first color filter CF1 disposed and overlap the non-light emitting region NPXA and the third color filter CF3 disposed on the first color filter CF1. In an embodiment of the present inventive concept, the blocking part BLP may include only a structure in which the first color filter CF1 and the third color filter CF3 are sequentially stacked. Alternatively, according to a process of processing the first color filter CF1 and the third color filter CF3, the blocking part BLP may include a structure in which the third color filter CF3 and the first color filter CF1 are sequentially stacked. However, the embodiment of the present inventive concept is not necessarily limited thereto, and the blocking part BLP may include a structure in which the second color filter CF2 and the third color filter CF3 are stacked.

According to an embodiment of the present inventive concept, each of the first to third color filters CF1, CF2 and CF3 may include a scatterer. The scatterer may be inorganic particles. For example, the scatterer may include at least one of Titanium dioxide (TiO₂), Zinc oxide (ZnO), Aluminum oxide (Al₂O₃), Silicon dioxide (SiO₂), or hollow silica. The scatterer may include any one of TiO₂, ZnO, Al₂O₃, SiO₂, or hollow silica, or may be a mixture of at least two materials selected from among TiO₂, ZnO, Al₂O₃, SiO₂, and hollow silica.

The overcoat layer OC may cover the front surface of the display panel DP and protect the display panel DP. The overcoat layer OC may have a thickness of about 1 μm to about 15 μm. The overcoat layer OC may at least partially cover the first to third color filters CF1, CF2, and CF3 and may be an organic layer for protecting the first to third color filters CF1, CF2, and CF3. The overcoat layer OC may include a photocurable organic material or a thermosetting organic material. However, the embodiment of the present inventive concept is not necessarily limited thereto, and the overcoat layer OC may include an inorganic material. The overcoat layer OC may have a high light absorption rate with a specific wavelength range. For example, the overcoat layer OC may include a pigment or dye having a high light absorption rate with a specific wavelength range. When the overcoat layer OC includes a pigment, the overcoat layer OC may include about 1 wt % to about 50 wt % of the pigment based on the total weight of the overcoat layer OC.

FIG. 5B is an enlarged view of the blocking part BLP according to an embodiment of the inventive concept. Referring to FIG. 5B, in the blocking part BLP, the first color filter CF1 and the third color filter CF3 may be sequentially stacked. According to an embodiment of the present inventive concept, the thickness Th4 of the blocking part BLP may be the same as the thickness Th1 of the first color filter CF1 and the thickness Th3 of the third color filter CF3 combined, which are disposed in the blocking part BLP. For example, the thickness Th4 of the blocking part BLP may be about 3.0 μm to about 10.0 μm. For example, the thickness Th4 of the blocking part BLP may be about 3.0 μm to about 7.5 μm. The thickness Th1 of the first color filter CF1 may be about 2.0 μm to about 4.5 μm, and the thickness Th3 of the third color filter CF3 may be about 1.0 μm to about 3.0 μm.

The blocking part BLP may have an optical density of about 3.0 to about 5.0. In addition, the reflectance of the blocking part BLP to the external light may be about 0.1 or less. The details of this will be described later.

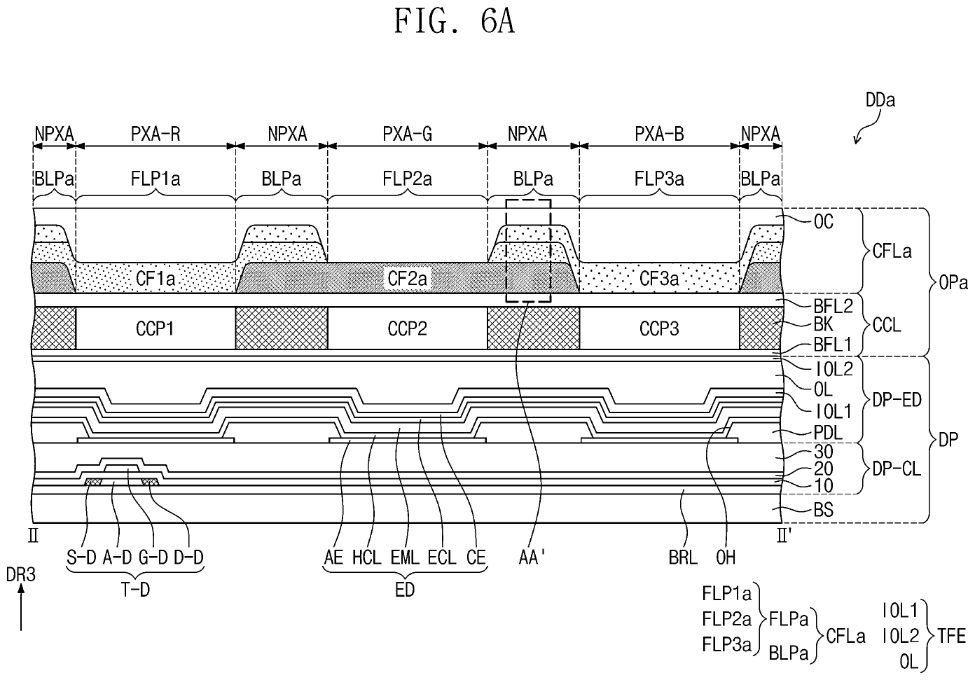

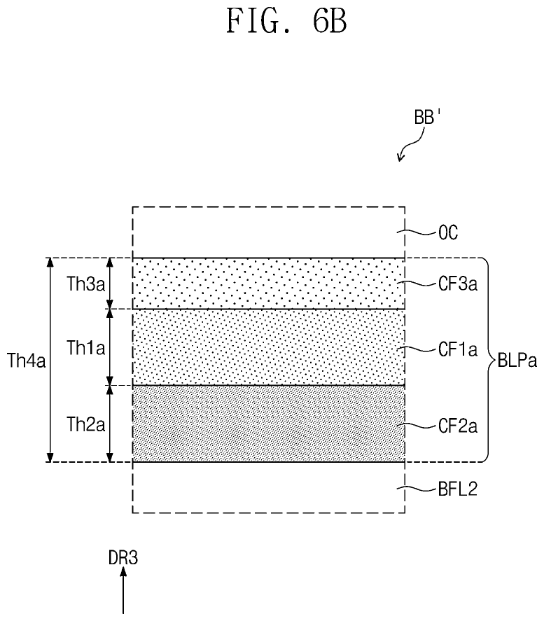

FIG. 6A is a cross-sectional view of a display device DDa according to an embodiment, taken along line II-II′ of FIG. 4. FIG. 6B is an enlarged view of region BB′ of FIG. 6A. To the extent that an element has not been described in detail, it may be assumed that the element is at least similar to corresponding elements that have been described in previous figures.

The light control panel OPa may include a light control layer CCL and a color filter layer CFLa disposed on the upper portion of the light control layer CCL. The first to third color filters CF1a, CF2a, and CF3a disposed in the color filter layer CFLa may be disposed in the same layer, corresponding to the first light emitting region PXA-R, the second light emitting region PXA-G, and the third light emitting region PXA-B, respectively. For example, the first to third color filters CF1a, CF2a, and CF3a may be disposed on the light control layer CCL, corresponding to the first light emitting region PXA-R, the second light emitting region PXA-G, and the third light emitting region PXA-B, respectively. The first to third color filters CF1a, CF2a, and CF3a may have the same height measured from the top surface of the light control layer CCL in the first light emitting region PXA-R, the second light emitting region PXA-G, and the third light emitting region PXA-B, respectively. In addition, the height measured from the top surface of a portion of the third color filter CF3a overlapping the non-light emitting region NPXA may be different from the height measured from the top surface of a portion of the third color filter CF3a overlapping the third light emitting region PXA-B. The top surface of a portion of the third color filter CF3a overlapping the non-light emitting region NPXA may be higher than the top surface of a portion of the third color filter CF3a overlapping the third light emitting region PXA-B. However, the embodiment of the inventive concept is not necessarily limited thereto, and unlike the configuration illustrated in FIG. 6A, the height of the third color filter CF3a overlapping the third light emitting region PXA-B may be relatively higher than those of the first and second color filters CF1a and CF2a overlapping the first light emitting region PXA-R and the second light emitting region PXA-G, respectively.

According to an embodiment of the present inventive concept, the color filter layer CFLa may include a filter part FLPa which overlaps the light emitting regions PXA-R, PXA-G, and PXA-B and in which one among the color filters CF1a, CF2a, and CF3a is disposed, and a blocking part BLPa which overlaps the non-light emitting region NPXA and in which at least two among the color filters CF1a, CF2a, and CF3a are disposed. For example, the filter part FLPa may include a first filter part FLP1a corresponding to the first color filter CF1a disposed in the first light emitting region PXA-R, a second filter part FLP2a corresponding to the second color filter CF2a disposed in the second light emitting region PXA-G, and a third filter part FLP3a corresponding to the third color filter CF3a disposed in the third light emitting region PXA-B.

The blocking part BLPa may be defined (or configured) by the first to third color filters CF1a, CF2a, and CF3a disposed in the non-light emitting region NPXA. For example, the blocking part BLPa may correspond to the first to third color filters CF1a, CF2a, and CF3a disposed and overlap the non-light emitting region NPXA. For example, the blocking part BLPa may be a part corresponding to the second color filter CF2a overlapping the non-light emitting region NPXA, the first color filter CF1a disposed on the second color filter CF2a, and the third color filter CF3a disposed on the first color filter CF1a. In an embodiment of the present inventive concept, the blocking part BLPa may include only a structure in which the second color filter CF2a, the first color filter CF1a, and the third color filter CF3a are sequentially stacked. However, the stacking order of the first color filter CF1a, the second color filter CF2a, and the third color filter CF3a formed on the blocking part BLPa may vary depending on a process of processing the first color filter CF1a, the second color filter CF2a, and the third color filter CF3a.

FIG. 6B is an enlarged view of the blocking part BLPa according to an embodiment of the present inventive concept. Referring to FIG. 6B, in the blocking part BLPa, the second color filter CF2a, the first color filter CF1a, and the third color filter CF3a may be sequentially stacked. According to an embodiment of the present inventive concept, the thickness Th4a of the blocking part BLPa may be the same as the thickness Th2a of the second color filter CF2a disposed in the blocking part BLPa, the thickness Th1a of the first color filter CF1a, and the thickness Th3a of the third color filter CF3a combined. For example, the thickness Th4a of the blocking part BLPa may be about 3.0 μm to about 10.0 μm. For example, the thickness Th4a of the blocking part BLPa may be about 4.0 μm to about 10.0 μm. The thickness Th1a of the first color filter CF1a may be about 1.0 μm to about 3.0 μm, the thickness Th2a of the second color filter CF2a may be about 2.0 μm to about 4.0 μm, and the thickness Th3a of the third color filter CF3a may be about 1.0 μm to about 3.0 μm.

The blocking part BLP may have an optical density of about 4.0 to about 5.0. In addition, the reflectance of the blocking part BLP to the external light may be about 0.1 or less. The details of this will be described later.

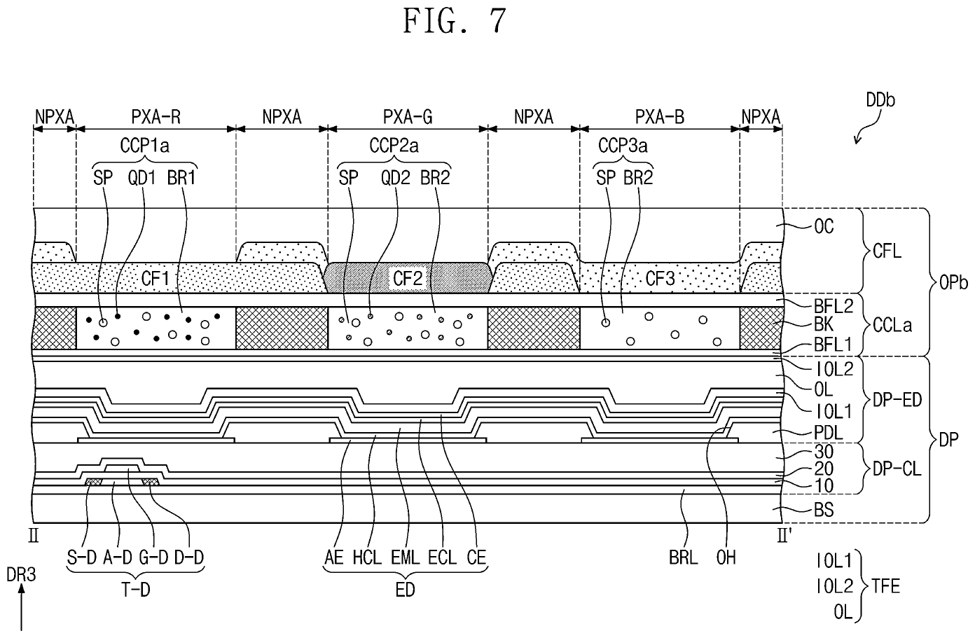

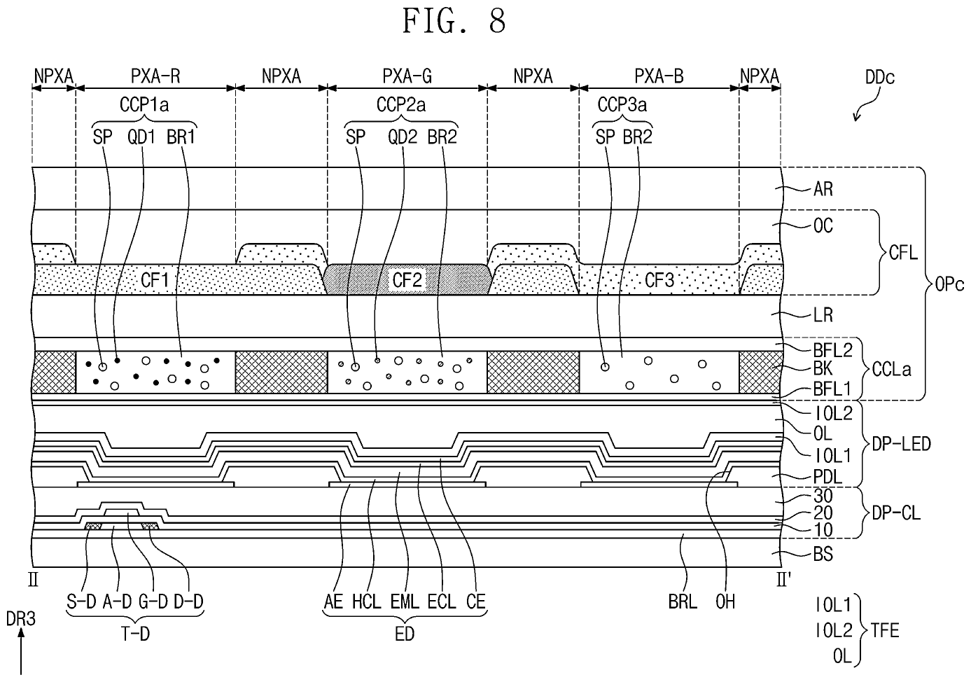

Each of FIGS. 7 and 8 is a cross-sectional view of a display device according to another embodiment of the present inventive concept. Hereinafter, components in the display devices DDb and DDc will be described in more detail with reference to FIGS. 7 and 8. To the extent that an element has not been described in detail, it may be assumed that the element is at least similar to corresponding elements that have been described in previous figures.

Referring to FIG. 7, the light control panel OPb may include a light control layer CCLa and a color filter layer CFL disposed on the upper portion of the light control layer CCLa. The light control layer CCLa may include a first light control part CCP1a containing a first quantum dot QD1 which converts first color light provided from the light emitting element ED into second color light, a second light control part CCP2a containing a second quantum dot QD2 which converts the first color light into third color light, and a third light control part CCP3a which transmits the first color light.

In an embodiment of the present inventive concept, the first light control part CCP1a may provide red light that is the second color light, and the second light control part CCP2a may provide green light that is the third color light. The third light control part CCP3a may provide blue light by transmitting the blue light that is the first color light provided from the light emitting element ED. For example, the first quantum dot QD1 may be a red quantum dot, and the second quantum dot QD2 may be a green quantum dot.

The quantum dots QD1 and QD2 may each have a core-shell structure, and the core of each of the quantum dots QD1 and QD2 may be selected from among a Group II-VI compound, a Group III-VI compound, a Group I-III-IV compound, a Group III-V compound, a Group IV-VI compound, a Group IV element, a Group IV compound, and a combination thereof.

The Group II-VI compound may be selected from the group consisting of a binary compound selected from the group consisting of cadmium selenide (CdSe), cadmium telluride (CdTe), cadmium sulfide (CdS), zinc sulfide (ZnS), zinc selenide (ZnSe), zinc telluride (ZnTe), zinc oxide (ZnO), mercury sulfide (HgS), mercury selenide (HgSe), mercury telluride (HgTe), magnesium selenide (MgSe), magnesium sulfide (MgS), and a mixture thereof, a ternary compound selected from the group consisting of cadmium selenosulfide (CdSeS), cadmium selenotelluride (CdSeTe), cadmium sulfidetelluride (CdSTe), zinc selenosulfide (ZnSeS), zinc selenotelluride (ZnSeTe), zinc sulfidetelluride (ZnSTe), mercury selenosulfide (HgSeS), mercury selenotelluride (HgSeTe), mercury sulfidetelluride (HgSTe), cadmium zinc sulfide (CdZnS), cadmium zinc selenide (CdZnSe), cadmium zinc telluride (CdZnTe), cadmium mercury sulfide (CdHgS), cadmium mercury selenide (CdHgSe), cadmium mercury telluride (CdHgTe), mercury zinc sulfide (HgZnS), mercury zinc selenide (HgZnSe), mercury zinc telluride (HgZnTe), magnesium zinc selenide (MgZnSe), magnesium zinc sulfide (MgZnS), and a mixture thereof, and a quaternary compound selected from the group consisting of mercury zinc telluride sulfide (HgZnTeS), cadmium zinc selenosulfide (CdZnSeS), cadmium zinc selenotelluride (CdZnSeTe), cadmium zinc sulfidetelluride (CdZnSTe), cadmium mercury selenosulfide (CdHgSeS), cadmium mercury selenotelluride (CdHgSeTe), cadmium mercury sulfidetelluride (CdHgSTe), mercury zinc selenosulfide (HgZnSeS), mercury zinc selenotelluride (HgZnSeTe), mercury zinc sulfidetelluride (HgZnSTe), and a mixture thereof.

The Group III-VI compound may include a binary compound such as indium sesquisulfide (In₂S₃) and indium sesquiselenide (In₂Se₃), as well as ternary compounds such as indium gallium sulfide (InGaS₃), indium gallium selenide (InGaSe₃) or any combination thereof.

The Group I-III-VI semiconductor compound may include a ternary compound such as silver indium sulfide (AgInS), silver indium disulfide (AgInS₂), copper indium sulfide (CuInS), copper indium disulfide (CuInS₂), silver gallium sulfide (AgGaS₂), copper gallium sulfide (CuGaS₂), copper gallium oxide (CuGaO₂), silver gallium oxide (AgGaO₂), silver aluminum oxide (AgAlO₂) or any combination thereof.

The Group III-V compound may be selected from the group consisting of a binary compound selected from the group consisting of gallium nitride (GaN), gallium phosphide (GaP), gallium arsenide (GaAs), gallium antimonide (GaSb), aluminum nitride (AlN), aluminum phosphide (AIP), aluminum arsenide (AlAs), aluminum antimonide (AlSb), indium nitride (InN), indium phosphide (InP), indium arsenide (InAs), indium antimonide (InSb) and a mixture thereof, a ternary compound selected from the group consisting of gallium nitride phosphide (GaNP), gallium nitride arsenide (GaNAs), gallium nitride antimonide (GaNSb), gallium phosphide arsenide (GaPAs), gallium phosphide antimonide (GaPSb), aluminum nitride phosphide (AlNP), aluminum nitride arsenide (AlNAs), aluminum nitride antimonide (AlNSb), aluminum phosphide arsenide (AlPAs), aluminum phosphide antimonide (AlPSb), indium gallium phosphide (InGaP), indium aluminum phosphide (InAlP), indium nitride phosphide (InNP), indium nitride arsenide (InNAs), indium nitride antimonide (InNSb), indium phosphide arsenide (InPAs), indium phosphide antimonide (InPSb, and a mixture thereof, and a quaternary compound selected from the group consisting of gallium aluminum nitride phosphide (GaAlNP), gallium aluminum nitride arsenide (GaAlNAs), gallium aluminum nitride antimonide (GaAlNSb), gallium aluminum phosphide arsenide (GaAlPAs), gallium aluminum phosphide antimonide (GaAlPSb), gallium indium nitride phosphide (GaInNP), gallium indium nitride arsenide (GaInNAs), gallium indium nitride antimonide (GaInNSb), gallium indium phosphide arsenide (GaInPAs), gallium indium phosphide antimonide (GaInPSb), indium aluminum nitride phosphide (InAlNP), indium aluminum nitride arsenide (InAlNAs), indium aluminum nitride antimonide (InAlNSb), indium aluminum phosphide arsenide (InAlPAs), indium aluminum phosphide antimonide (InAlPSb), and a mixture thereof. Meanwhile, the Group III-V compound may further include a Group II metal. For example, InZnP, etc., may be selected as a Group III-II-V compound.

The Group IV-VI compound may be selected from the group consisting of a binary compound selected from the group consisting of tin sulfide (SnS), tin selenide (SnSe), tin telluride (SnTe), lead sulfide (PbS), lead selenide (PbSe), lead telluride (PbTe), and a mixture thereof, a ternary compound selected from the group consisting of SnSeS, SnSeTe, SnSTe, PbSeS, PbSeTe, PbSTe, SnPbS, SnPbSe, SnPbTe, and a mixture thereof, and a quaternary compound selected from the group consisting of SnPbSSe, SnPbSeTe, SnPbSTe, and a mixture thereof. The Group IV element may be selected from the group consisting of Si, Ge, and a mixture thereof. The Group IV compound may be a binary compound selected from the group consisting of SiC, SiGe, and a mixture thereof.

In this case, the binary compound, the ternary compound, or the quaternary compound may be present in a particle with a uniform concentration distribution, or may be present in the same particle with a partially different concentration distribution. In addition, a core-shell structure in which one quantum dot surrounds another quantum dot may be possible. In the core-shell structure, the interface of the shell may have a concentration gradient in which the concentration of an element present in the shell becomes lower towards the core.

In some embodiments, the quantum dot may have the above-described core-shell structure including a core containing nanocrystals and a shell surrounding the core. The shell of the quantum dot may serve as a protection layer to prevent the chemical deformation of the core so as to maintain semiconductor properties, and/or a charging layer to impart electrophoresis properties to the quantum dot. The shell may be a single layer or a multilayer. An example of the shell of the quantum dots may include a metal or non-metal oxide, a semiconductor compound, or a combination thereof.

For example, the metal or non-metal oxide may be a binary compound such as silicon dioxide (SiO₂), aluminum oxide (Al₂O₃), titanium dioxide (TiO₂), zinc oxide (ZnO), manganese (II) oxide (MnO), manganese (III) oxide (Mn₂O₃), manganese (II,III) oxide (Mn₃O₄), copper (II) oxide (CuO), iron (II) oxide (FeO), iron (III) oxide (Fe₂O₃), iron (II,III) oxide (Fe₃O₄), cobalt (II) oxide (CoO), cobalt (II,III) oxide (Co₃O₄), and nickel (II) oxide (NiO), or a ternary compound such as magnesium aluminate (MgAl₂O₄), cobalt ferrite (CoFe₂O₄), nickel ferrite (NiFe₂O₄), and cobalt manganese oxide (CoMn₂O₄) but the present embodiment of the inventive concept is not necessarily limited thereto.

In addition, the semiconductor compound may be, for example, cadmium sulfide (CdS), cadmium selenide (CdSe), cadmium telluride (CdTe), zinc sulfide (ZnS), zinc selenide (ZnSe), zinc telluride (ZnTe), zinc sulfide selenide (ZnSeS), zinc telluride selenide (ZnTeS), gallium arsenide (GaAs), gallium phosphide (GaP), gallium antimonide (GaSb), mercury sulfide (HgS), mercury selenide (HgSe), mercury telluride (HgTe), indium arsenide (InAs), indium phosphide (InP), indium gallium phosphide (InGaP), indium antimonide (InSb), aluminum arsenide (AlAs), aluminum phosphide (AP), aluminum antimonide (AlSb), etc., but the embodiment of the present inventive concept is not necessarily limited thereto.

The quantum dots QD1 and QD2 may have a full width of half maximum (FWHM) of a light emission wavelength spectrum of about 45 nm or less, preferably about 40 nm or less, and more preferably about 30 nm or less, and color purity or color reproducibility may be improved in the above range. In addition, light emitted through these quantum dots QD1 and QD2 may be emitted in all directions so that a wide viewing angle may be improved.

In addition, although each form of the quantum dots QD1 and QD2 is not particularly limited as long as it is a form commonly used in the art, a quantum dot in the form of spherical, pyramidal, multi-arm, or cubic nanoparticles, nanotubes, nanowires, nanofibers, nanoplate particles, etc. may be used.

The size of the quantum dots QD1 and QD2 or the element ratio in the compound of the quantum dots QD1 and QD2 may be adjusted. Accordingly, the quantum dots may have various light emission colors such as blue, red, and green. For example, the adjustment of the size of the quantum dots QD1 and QD2 or the elemental ratio in the compound of the quantum dots QD1 and QD2 may be selected to emit red, green, and/or blue light. In an embodiment of the present inventive concept, the quantum dot QD1 included in the first light control part CCP1a overlapping the first light emitting region PXA-R may have a red emission color, and the quantum dot QD2 included in the second light control part CCP2a overlapping the second light emitting region PXA-G may have a green emission color. As the particle size of the quantum dots QD1 and QD2 becomes smaller, the quantum dots QD1 and QD2 may emit light in the short wavelength region. For example, in the quantum dots QD1 and QD2 having the same core, the particle size of the quantum dot that emits green light may be smaller than that of the quantum dot that emits red light. In addition, in the quantum dots QD1 and QD2 having the same core, the particle size of the quantum dot that emits blue light may be smaller than that of the quantum dot that emits green light. However, the embodiment of the present inventive concept is not necessarily limited thereto, and even in the quantum dots QD1 and QD2 having the same core, the particle size may be adjusted according to forming-materials and thickness of a shell.

When the quantum dots QD1 and QD2 have various emission colors such as blue, red, and green, the quantum dots QD1 and QD2 having different emission colors may have different core materials.

The light control layer CCL may further include a scatterer SP. The first light control part CCP1a may include the first quantum dot QD1 and the scatterer SP, the second light control part CCP2a may include the second quantum dot QD2 and the scatterer SP, and the third light control part CCP3a might not include any quantum dot but include the scatterer SP.

The scatterer SP may be inorganic particles. For example, the scatterer SP may include at least one of titanium dioxide (TiO₂), zinc oxide (ZnO), aluminum oxide (Al₂O₃), and silicon dioxide (SiO₂), or hollow silica. The scatterer SP may include any one of TiO₂, ZnO, Al₂O₃, SiO₂, or hollow silica, or may be a mixture of at least two materials selected from among TiO₂, ZnO, Al₂O₃, SiO₂, and hollow silica.

The first light control part CCP1a, the second light control part CCP2a, and the third light control part CCP3a each may include base resins BR1, BR2, and BR3 in which the quantum dots QD1 and QD2 and the scatterer SP are dispersed. In an embodiment of the present inventive concept, the first light control part CCP1a may include the first quantum dot QD1 and the scatterer SP dispersed in a first base resin BR1, the second light control part CCP2a may include the second quantum dot QD2 and the scatterer SP dispersed in a second base resin BR2, and the third light control part CCP3a may include the scatterer SP dispersed in a third base resin BR3. The base resins BR1, BR2, and BR3 are media in which the quantum dots QD1 and QD2 and the scatterer SP are dispersed, and may be formed of various resin compositions, which may be generally referred to as a binder. For example, the base resins BR1, BR2, and BR3 may be acrylic-based resins, urethane-based resins, silicone-based resins, epoxy-based resins, etc. The base resins BR1, BR2, and BR3 may be transparent resins. In an embodiment of the present inventive concept, the first base resin BR1, the second base resin BR2, and the third base resin BR3 may be the same as or different from each other.

Referring to FIG. 8, in the display device DDc according to an embodiment of the present inventive concept, the light control panel OPc may further include an anti-reflection layer AR disposed on the color filter layer CFL. The anti-reflection layer AR may include a high refractive layer and a low refractive layer. For example, the anti-reflection layer AR may have a structure in which the high refractive layer and the low refractive layer are alternately stacked. The anti-reflective layer AR may include any one of silicon nitride (Si₃N₄), silicon nitride-x (SiNx), silicon dioxide (SiO₂), aluminum oxide (Al₂O₃), niobium dioxide (Nb₂O₂), aluminum nitride (AlN), silicon monoxide (SiO), aluminum oxynitride (AlOxNy), silicon oxynitride (SiOxNy), silicon aluminum oxynitride (SiuAlvOxNy), magnesium fluoride (MgF₂), magnesium oxide (MgO), titanium dioxide (TiO₂), germanium dioxide (GeO₂), magnesium aluminum oxide (MgAl₂O₄), barium fluoride (BaF₂), calcium fluoride (CaF₂), dysprosium trifluoride (DyF₃), ytterbium trifluoride (YbF₃), yttrium trifluoride (YF₃), cerium trifluoride (CeF₃), tantalum pentoxide (Ta₂O₅), hafnium dioxide (HfO₂), zirconium dioxide (ZrO₂), molybdenum trioxide (MoO₃), or a combination thereof. The display device DDc according to an embodiment of the present inventive concept may further include the anti-reflection layer AR and the reflection of external light may be reduced, and thus display efficiency may be increased.

The light control panel OPc according to an embodiment of the present disclosure may further include a low refractive layer LR between the light control layer CCLa and the color filter layer CFL. The low refractive layer LR may be a layer having a refractive index lower than that of the color filter layer CFL and the light control layer CCLa which are adjacent to the low refractive layer LR. The low refractive layer LR may totally reflect a portion of the blue light emitted from the light control layer CCLa toward the color filter layer CFL to be re-incident onto the light control layer CCLa. The blue light may be light emitted from the light emitting element ED. A portion of the blue light may be re-incident onto the first light control part CCP1a or the second light control part CCP2a included in the light control layer CCLa. As described above, the first light control part CCP1a may change the re-incident blue light into red light, and the third color control part CCP2a may change the re-incident blue light into green light. Such a recirculation of light may increase the light efficiency of the display device DDc.

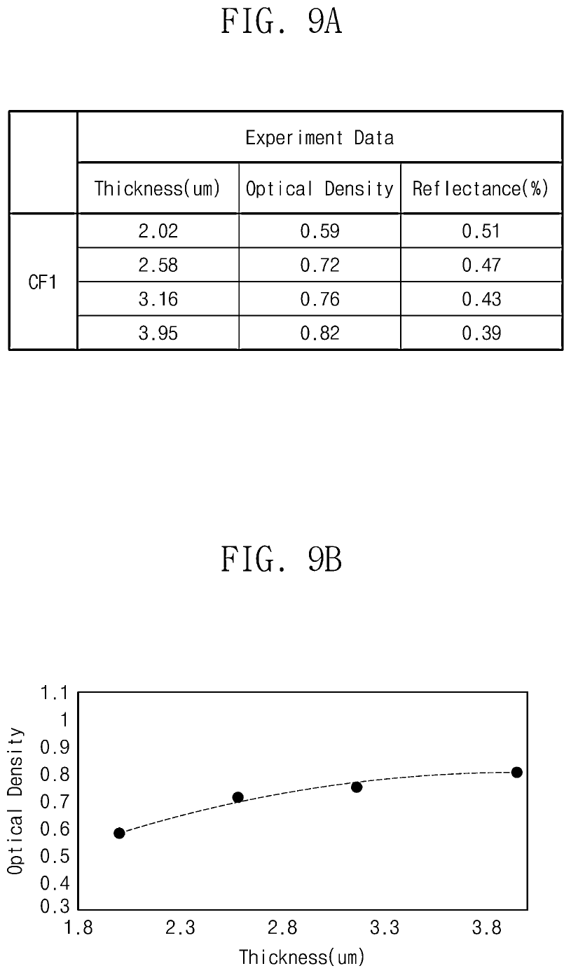

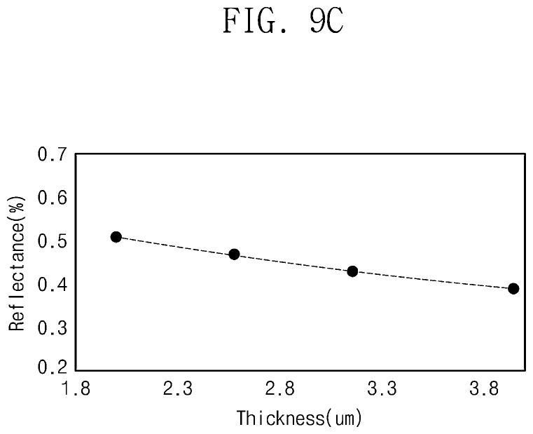

FIGS. 9A to 9C are diagrams showing optical densities and reflectances depending on thicknesses of the first color filter illustrated in FIG. 5A. For example, FIG. 9A is a table showing optical densities and reflectances depending on the thicknesses of the first color filter CF1, FIG. 9B is a graph showing optical densities depending on the thicknesses of the first color filter CF1, and FIG. 9C is a graph showing reflectances depending on the thicknesses of the first color filter CF1.

Referring to FIGS. 9A and 9B, it may be confirmed that the optical density increases as the thickness of the first color filter CF1 increases. Here, the optical density may indicate how much light energy is blocked by an optical filter which reduces the transmittance of light having a specific wavelength. When the optical density is indicated as OD, the OD value may be expressed as a log value of a ratio of the intensity (o) of light incident on the material and the intensity of transmitted light (2) as shown in Equation 1 below:

$$OD = log \frac{{I}_{0}}{{I}_{1}} \qquad [ Equation 1 ]$$

With reference to the equation of the optical density, the high optical density of the optical filter may mean that the transmittance of the optical filter is low, and the low optical density of the optical filter may mean that the transmittance of the optical filter is high.

In the method of measuring the optical density, a specimen is prepared after a specific sample (e.g., the first color filter CF1 of the inventive concept) may be coated on a glass substrate. Here, the glass substrate may be a transparent substrate having a transmittance of 100%. Then, a spectrophotometer or an OD meter may be used to measure the transmittance of a specific wavelength (e.g., 550 nm) or a wavelength of visible light. Here, the measured transmittance may be expressed as an OD value by Equation 1 above.

According to the current embodiment of the present inventive concept, the optical density depending on the thickness of the first color filter CF1 may be a value when external light having a wavelength of about 550 nm is incident onto the first color filter CF1. It may be confirmed that when the thickness of the first color filter CF1 is about 2.02 μm, the optical density of the first color filter CF1 is about 0.59, when the thickness of the first color filter CF1 is about 2.58 μm, the optical density of the first color filter CF1 is about 0.72, when the thickness of the first color filter CF1 is about 3.16 μm, the optical density of the first color filter CF1 is about 0.76, and when the thickness of the first color filter CF1 is about 3.95 μm, the optical density of the first color filter CF1 is about 0.82.

Referring to FIGS. 9A and 9C, it may be confirmed that the reflectance of the first color filter CF1 to the external light decreases as the thickness of the first color filter CF1 increases. Here, the reflectance according to the current embodiment is Specular Component Excluded (SCE), which means reflectance according to diffuse light excluding specular light. It may be confirmed that when the thickness of the first color filter CF1 is about 2.02 μm, the reflectance of the first color filter CF1 is about 0.51%, when the thickness of the first color filter CF1 is about 2.58 μm, the reflectance of the first color filter CF1 is about 0.47%, when the thickness of the first color filter CF1 is about 3.16 μm, the reflectance of the first color filter CF1 is about 0.43%, and when the thickness of the first color filter CF1 is about 3.95 μm, the reflectance of the first color filter CF1 is about 0.39%.

Referring to FIGS. 9A to 9C, as the thickness of the first color filter CF1 increases, the optical density of the first color filter CF1 may increase, and the reflectance of the first color filter CF1 may decrease. For example, as the optical density of the first color filter CF1 increases, the reflectance of the first color filter CF1 may decrease.

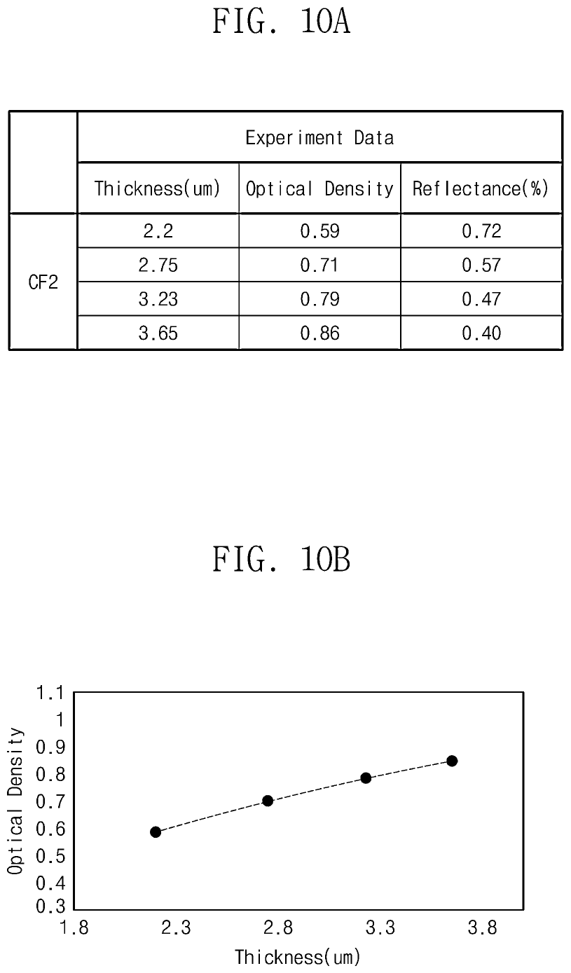

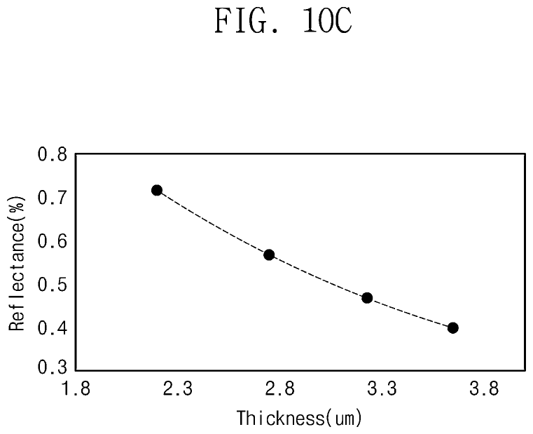

FIGS. 10A to 10C are diagrams showing optical densities and reflectances depending on thicknesses of the second color filter illustrated in FIG. 5A. For example, FIG. 10A is a table showing optical densities and reflectances depending on the thicknesses of the second color filter CF2, FIG. 10B is a graph showing optical densities depending on the thicknesses of the second color filter CF2, and FIG. 10C is a graph showing reflectances depending on the thicknesses of the second color filter CF2. To the extent that an element has not been described in detail, it may be assumed that the element is at least similar to corresponding elements that have been described in previous figures.

Referring to FIGS. 10A and 10B, it may be confirmed that the optical density increases as the thickness of the second color filter CF2 increases. According to the current embodiment of the present inventive concept, the optical density depending on the thickness of the second color filter CF2 may be a value when external light having a wavelength of about 550 nm is incident onto the second color filter CF2. It may be confirmed that when the thickness of the second color filter CF2 is about 2.20 μm, the optical density of the second color filter CF2 is about 0.59, when the thickness of the second color filter CF2 is about 2.75 μm, the optical density of the second color filter CF2 is about 0.71, when the thickness of the second color filter CF2 is about 3.23 μm, the optical density of the second color filter CF2 is about 0.79, and when the thickness of the second color filter CF2 is about 3.65 μm, the optical density of the second color filter CF2 is about 0.86.

Referring to FIGS. 10A and 10C, it may be confirmed that the reflectance of the second color filter CF2 to the external light decreases as the thickness of the second color filter CF2 increases. It may be confirmed that when the thickness of the second color filter CF2 is about 2.20 μm, the reflectance of the second color filter CF2 is about 0.72%, when the thickness of the second color filter CF2 is about 2.75 μm, the reflectance of the second color filter CF2 is about 0.57%, when the thickness of the second color filter CF2 is about 3.23 μm, the reflectance of the second color filter CF2 is about 0.47%, and when the thickness of the second color filter CF2 is about 3.65 μm, the reflectance of the second color filter CF2 is about 0.40%.

Referring to FIGS. 10A to 10C, as the thickness of the second color filter CF2 increases, the optical density of the second color filter CF2 may increase, and the reflectance of the second color filter CF2 may decrease. For example, as the optical density of the second color filter CF2 increases, the reflectance of the second color filter CF2 may decrease.

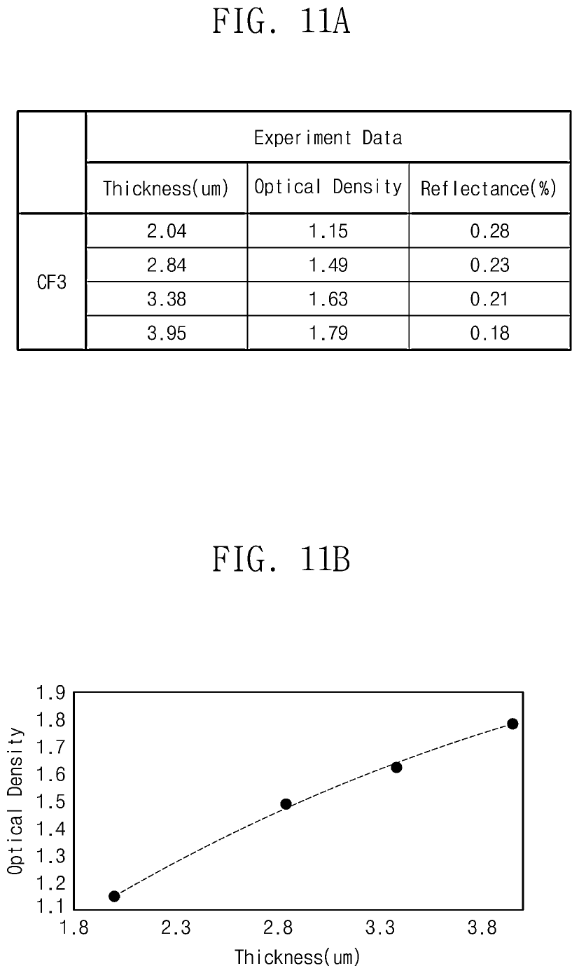

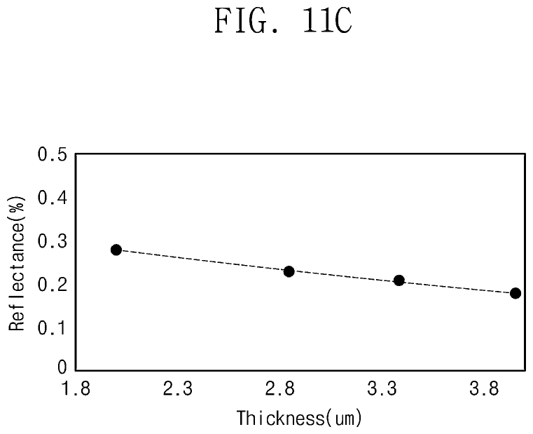

FIGS. 11A to 11C are diagrams showing optical densities and reflectances depending on thicknesses of the third color filter illustrated in FIG. 5A. For example, FIG. 11A is a table showing optical densities and reflectances depending on the thicknesses of the third color filter CF, FIG. 11B is a graph showing optical densities depending on the thicknesses of the third color filter CF3, and FIG. 10C is a graph showing reflectances depending on the thicknesses of the third color filter CF3.

Referring to FIGS. 11A and 11B, it may be confirmed that the optical density increases as the thickness of the third color filter CF3 increases. According to the current embodiment of the present inventive concept, the optical density depending on the thickness of the third color filter CF3 may be a value when external light having a wavelength of about 550 nm is incident onto the third color filter CF3. It may be confirmed that when the thickness of the third color filter CF3 is about 2.04 μm, the optical density of the third color filter CF3 is about 1.15, when the thickness of the third color filter CF3 is about 2.84 μm, the optical density of the third color filter CF3 is about 1.49, when the thickness of the third color filter CF3 is about 3.38 μm, the optical density of the third color filter CF3 is about 1.63, and when the thickness of the third color filter CF3 is about 3.95 μm, the optical density of the third color filter CF3 is about 1.79.

Referring to FIGS. 11A and 11C, it may be confirmed that the reflectance of the third color filter CF3 to the external light decreases as the thickness of the third color filter CF3 increases. It may be confirmed that when the thickness of the third color filter CF3 is about 2.04 μm, the reflectance of the third color filter CF3 is about 0.28%, when the thickness of the third color filter CF3 is about 2.84 μm, the reflectance of the third color filter CF3 is about 0.23%, when the thickness of the third color filter CF3 is about 3.38 μm, the reflectance of the third color filter CF3 is about 0.21%, and when the thickness of the third color filter CF3 is about 3.95 μm, the reflectance of the third color filter CF3 is about 0.18%.

Referring to FIGS. 11A to 11C, as the thickness of the third color filter CF3 increases, the optical density of the third color filter CF3 may increase, and the reflectance of the third color filter CF3 may decrease. For example, as the optical density of the third color filter CF3 increases, the reflectance of the third color filter CF3 may decrease.

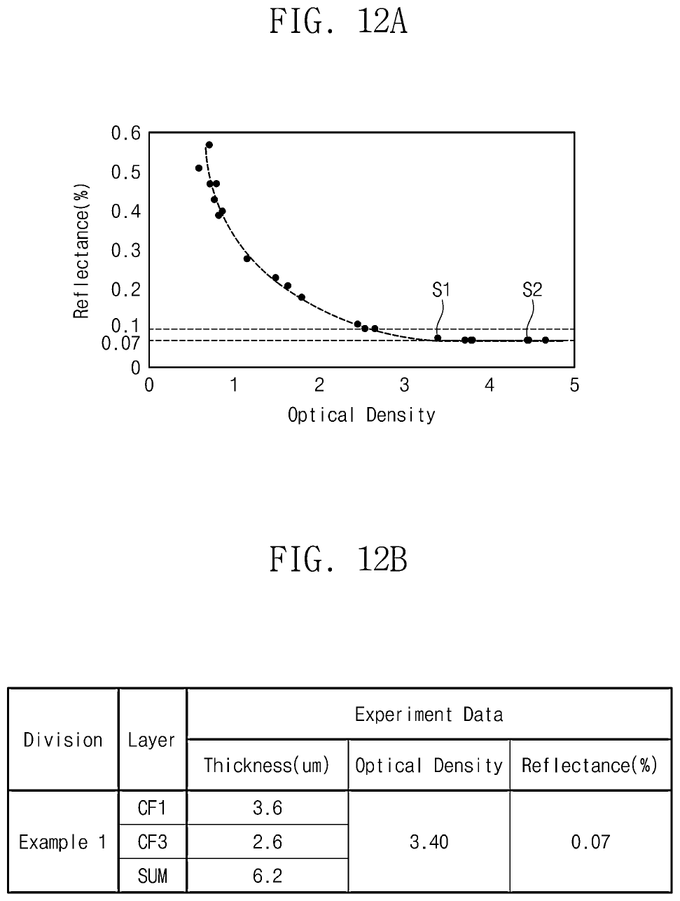

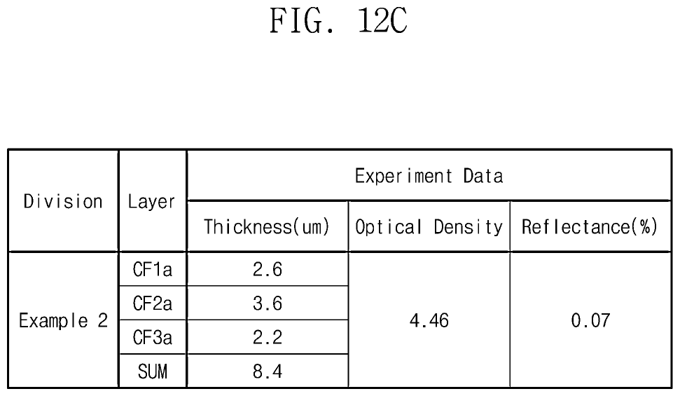

FIGS. 12A to 12C are diagrams showing optical densities and reflectances depending on thicknesses of blocking parts illustrated in FIGS. 5A and 6A. For example, FIG. 12A is a graph showing the reflectances depending on the optical densities of the blocking parts BLP and BLPa illustrated in FIGS. 5A and 6A,

FIG. 12B is a table showing optical densities and reflectances depending on the thicknesses at a first point S1 shown in FIG. 12A, and FIG. 12C is a table showing optical densities and reflectances depending on the thicknesses at a second point S2 shown in FIG. 12A.

Referring to FIG. 12A, it may be confirmed that as the optical density increases, the reflectance decreases. For example, it may be confirmed that when the optical density is around 3.0, the reflectance converges similarly to about 0.1%. For example, the reflectance is about 0.1% when the optical density is about 2.5, and the reflectance may converge to about 0.07% when the optical density is about 3.0 or more.

When the optical densities of the blocking parts BLP and BLPa illustrated in FIGS. 5A and 6A are less than about 3.0, the reflectance of the blocking parts BLP and BLPa may increase to about 0.1% or more. When the blocking parts BLP and BLPa having high reflectance are provided in the display devices DD and DDa, external light incident from the outside may be reflected, and a phenomenon in which the blocking parts BLP and BLPa are viewed by a user may occur due to the reflected external light. In order to reduce the phenomenon in which the blocking parts BLP and BLPa are viewed by the user, the reflectance of the blocking parts BLP and BLPa maybe set to about 0.1% or less. For example, referring back to FIG. 12A, it can be seen that the optical density of the blocking portions BLP and BLPa maybe about 3.0 or more in order for the reflectance of the blocking portions BLP and BLPa to be set to about 0.1% or less.

Referring to FIGS. 5A, 5B, and 12B, the optical density and reflectance depending on the thickness Th4 of the blocking part BLP may be confirmed. For example, when the thickness Th1 of the first color filter CF1 is about 3.6 μm and the thickness Th3 of the third color filter CF3 is about 2.6 μm and thus the thickness Th4 of the blocking part BLP is about 6.2 μm, the optical density of the blocking part BLP may be about 3.40 and the reflectance may be about 0.07%. In addition, since the thickness Th1 of the first color filter CF1 is set to be about 2.0 μm to about 4.5 μm, and the thickness Th3 of the third color filter CF3 is set to be about 1.0 μm to about 3.0 μm, the optical density of the blocking part BLP may be about 3.0 to about 5.0, and the reflectance of the blocking part BLP to the external light may be about 0.1 or less. If the optical density is set to be about 5.0 or more, the external light may pass through the blocking part BLP and be reflected from the upper surface of the light control layer CCL. For example, as the optical density is set to be about 3.0 to about 5.0, the absorption rate to the external light in the blocking part BLP may be increased and the reflectance to the external light may be decreased. As a result, a reliability of the display device DD may increase.

Referring to FIGS. 6A, 6B, and 12C, the optical density and reflectance depending on the thickness Th4a of the blocking part BLPa may be confirmed. For example, when the thickness Th1a of the first color filter CF1a is about 2.6 μm, the thickness Th2a of the second color filter CF2a is about 3.6 μm, and the thickness Th3a of the third color filter CF3a is about 2.2 μm, and thus the thickness Th4a of the blocking part BLPa is about 8.4 μm, the optical density of the blocking part BLPa may be about 4.46, and the reflectance may be about 0.07%. In addition, when the thickness Th1a of the first color filter Cf1a is set to be about 1.0 μm to about 3.0 μm, the thickness Th2a of the second color filter CF2a is set to be about 2.0 μm to about 4.0 μm, and the thickness Th3a of the third color filter CF3a is set to be about 1.0 μm to about 3.0 μm, the optical density of the blocking part BLPa may be about 4.0 to about 5.0, and the reflectance to the external light of the blocking part BLPa may be about 0.1 or less.

According to the present inventive concept, the color filter layer CFL disposed on the display panel DP may include filter parts FLP in which a single type of color filters CF1, CF2 and CF3 are disposed, and a blocking part BLP in which at least two color filters CF1, CF2 and CF3 overlap. The thickness of the blocking part BLP may be set to be about 3.0 μm to about 10.0 μm, and the optical density of the blocking part BLP may be set to be about 3.0 or more. Accordingly, the reflection of external light incident from the outside of the display device DD on the top surface of the blocking part BLP may be reduced, thereby reducing the phenomenon that the blocking part BLP is viewed by the user, and as a result, the reliability of the display device DD may increase.

Although the present inventive concept has been described with reference to a preferred embodiment of the inventive concept, it will be understood that the inventive concept should not be necessarily limited to these preferred embodiments but various changes and modifications can be made by those skilled in the art without departing from the spirit and scope of the inventive concept.

What is claimed is:

1. A display device, comprising:
a display panel including a plurality of light emitting regions in which a plurality of light emitting elements are disposed and a non-light emitting region disposed adjacent to the light emitting regions; and
a color filter layer disposed on the display panel,
wherein the color filter layer comprises:
a plurality of filter parts which overlap the light emitting regions, respectively, and in which a single type of color filter is disposed; and
a blocking part which overlaps the non-light emitting region and in which at least two color filters overlap,
wherein the blocking part has a thickness of about 3.0 μm to about 10.0 μm, and an optical density of about 3.0 or more.

2. The display device of claim 1, wherein the color filter layer comprises:
a first color filter configured to transmit a first color light;
a second color filter configured to transmit a second color light; and
a third color filter configured to transmit a third color light.

3. The display device of claim 2, wherein the blocking part is formed by stacking a portion of the first color filter and a portion of the third color filter.

4. The display device of claim 3, wherein the blocking part has an optical density of about 3.0 to about 5.0.

5. The display device of claim 3, wherein the first color filter disposed in the blocking part has a thickness of about 2.0 μm to about 4.5 μm, and
wherein the third color filter disposed in the blocking part has a thickness of about 1.0 μm to about 3.0 μm.

6. The display device of claim 2, wherein the blocking part is formed by stacking a portion of each of the first to third color filters.

7. The display device of claim 6, wherein the blocking part has an optical density of about 4.0 to about 5.0.

8. The display device of claim 6, wherein the first color filter disposed in the blocking part has a thickness of about 1.0 μm to about 3.0 μm,
wherein the second color filter disposed in the blocking part has a thickness of about 2.0 μm to about 4.0 μm, and
wherein the third color filter disposed in the blocking part has a thickness of about 1.0 μm to about 3.0 μm.

9. The display device of claim 2, wherein the first color filter comprises a first pigment,
wherein the second color filter comprises a second pigment, and
wherein the third color filter comprises a third pigment.

10. The display device of claim 9, wherein each of the first to third color filters further comprises a scatterer.

11. The display device of claim 2, wherein the color filter layer further comprises an overcoat layer at least partially covering the first to third color filters.

12. The display device of claim 2, wherein one color filter among the first to third color filters is disposed in each of the filter parts.

13. The display device of claim 1, wherein a reflectance to external light of the blocking part is about 0.1 or less.

14. The display device of claim 1, wherein each of the light emitting elements emits the first color light, and in a plan view, the display device includes a first pixel region configured to emit the second color light different from the first color light, a second pixel region configured to emit the third color light different from the first and second color lights, and a third pixel region configured to emit the first color light.

15. The display device of claim 14, further comprising a light control layer disposed between the display panel and the color filter layer,
wherein the light control layer comprises:
a first light control part at least partially overlapping the first pixel region and convert the first color light into the second color light;
a second light control part at least partially overlapping the second pixel region and convert the first color light into the third color light; and
a third light control part at least partially overlapping the third pixel region and transmit the first color light.

16. The display device of claim 15, further comprising:
a low refractive layer disposed between the light control layer and the color filter layer; and
an anti-reflection layer disposed on the color filter layer.

17. A display device, comprising:
a display panel including a plurality of light emitting regions in which a plurality of light emitting elements are disposed and a non-light emitting region disposed adjacent to the light emitting regions;
a light control layer disposed on the display panel; and
a color filter layer disposed on the light control layer,
wherein the color filter layer comprises:
a plurality of filter parts which overlap the light emitting regions, respectively, and in which a single type of color filter is disposed; and
a blocking part which overlaps the non-light emitting region and in which at least two color filters overlap,
wherein the blocking part has an optical density of about 3.0 to about 5.0.

18. The display device of claim 17, wherein the color filter layer comprises:
a first color filter configured to transmit first color light;
a second color filter configured to transmit second color light; and
a third color filter configured to transmit third color light.

19. The display device of claim 18, wherein the blocking part is formed by stacking a portion of the first color filter and a portion of the third color filter, and the blocking part has a thickness of about 3.0 μm to about 7.5 μm.

20. The display device of claim 17, wherein a reflectance to external light of the blocking part is about 0.1 or less.
